(19) United States
(12) Patent Application Publication
(10) Pub. No.: US 2021/0320045 A1
(43) Pub. Date: Oct. 14, 2021

(54) THERMAL MANAGEMENT STRUCTURES FOR NITRIDE-BASED HEAT GENERATING SEMICONDUCTOR DEVICES

(71) Applicant: Raytheon Company, Waltham, MA (US)

(72) Inventors: Kiuchul Hwang, Amherst, NH (US); Nicholas J. Kolias, Winchester, MA (US)

(73) Assignee: Raytheon Company, Waltham, MA (US)

(21) Appl. No.: 16/844,385

(22) Filed: Apr. 9, 2020

(51) Int. Cl. H01L 23/34; H01L 23/373

(52) U.S. Cl. CPC H01L 23/345; H01L 23/3737; H01L 23/3732

(57) ABSTRACT

A semiconductor structure having: a crystalline substrate; a single crystalline semiconductor layer grown on the substrate; and a heat generating semiconductor device formed on a portion of the single crystalline layer. The substrate has an aperture in a selected portion thereof disposed in regions in the semiconductor layer under the heat generating device the aperture extending from a bottom portion of the substrate to the single crystalline semiconductor layer. Single crystalline or polycrystalline, thermal conductive material is disposed in the aperture, such material filling the aperture and extending from the bottom of the substrate, to and in direct contact with, the semiconductor layer.

### TECHNICAL FIELD

This disclosure relates generally to thermal management structures and more particularly to thermal management structures of nitride-based heat generating devices.

### BACKGROUND OF THE INVENTION

As is known in the art, Group III-Nitride based Diodes, FETs (Field Effect Transistors) and HBTs (Heterojunction Bipolar Transistors) using wide bandgap materials such as GaN, AlGaN, InN, AlN, InAlN, ScAlN, and various Group III-N compounds have been widely used for high power RF/Microwave applications because of 5 to 10 times better performances than other conventional semiconductors such as silicon and GaAs. Even though the technology and materials have a potential to generate higher power density, the power level is compromised because of the requirement of an effective thermal management technology. Power devices generate large amounts of heat during the operation. See for example, R. E. Leoni, N. J. Kolias, P. Jablonski, F. Altunkilic, E. Johnson, and W. Bourcy, “Raytheon High Power Density GaN Technology” 2017 IEEE Compound Semiconductor Integrated Circuit Symposium Dig., Oct 2017, that describes shows GaN transistors producing 50 W/mm of output power and also ˜50 W/mm of dissipated heat.

If the generated heat is not dissipated quickly, the performance of transistors is degraded due to rising temperature. Group III-Nitride materials have higher thermal conductivity than GaAs and InP materials. Therefore, nitride-based materials such as GaN, AlN, InN, and SiC, make it an ideal candidate for power devices. For example, the silicon carbide (SiC) substrate material upon which the GaN is grown, enables approximately 6 times the thermal dissipation potential of GaAs enabling lower power droop, lower temperatures and higher efficiencies during the device operation at higher voltage and current However, even with the high thermal conductivity of SiC, the performance is thermally limited, motivating the desire to insert even higher thermal conductivity materials near the heat generating areas of the device.

As is also known in the art, for last decade, work has been done to develop a technology to combine GaN based power devices with synthetic diamond, which is well-known as the best thermal conductivity material, to manage the rising temperature of the devices during operation. D. C. Dumka and P. Saunier, “AlGaN/GaN HEMTs on diamond substrate,” in Proc. IEEE DRC Conf. Dig, 2007, pp. 31-32, G. H. Jessen, J. K. Gillespie, Y-F. Wu, G. D. Via, A. Crespo, D. Langley, J. Wasserbauer, F. Faili, D. Francis, D. Babic, F. Ejeckam, S. Guo, and I. Eliashevich, “AlGaN/GaN HEMT on Diamond Technology,” in Proc. IEEE Compound Semicond. Ingter. Circuit Symp. Tech. Dig., 2006, pp. 271-274, and F. Ejeckam, “GaN-on-diamond: A Brief history,” in IEEE L. Eastman conf. Dig, 2014 have reported technologies that bond a thin GaN wafer onto diamond substrates or wafers. Technical challenges have hampered the development, for example, cracks due to CTE (Coefficient of Thermal Expansion) mismatch between GaN and diamond wafers, difficulty to bond two wafers, compatibility of process such as high temperature alloy, etc.

### SUMMARY OF THE INVENTION

In accordance with the present disclosure, a semiconductor structure is provided having: a crystalline substrate; a single crystalline semiconductor layer grown on the substrate; and a heat generating semiconductor device formed on a portion of the single crystalline layer. The substrate has an aperture entirely through a selected portion thereof disposed under the heat generating semiconductor device, the aperture extending from a bottom portion of the substrate to the single crystalline semiconductor layer. Single crystalline or polycrystalline, heat conductive material, is disposed in the aperture, such material filling the aperture and extending from the bottom of the substrate, to and in direct contact with, the semiconductor layer.

In one embodiment the substrate is silicon or silicon carbide.

In one embodiment, the heat generating device is a transistor or diode.

In one embodiment, the semiconductor layer is a Group III-nitride.

In one embodiment, the single crystalline or polycrystalline, heat conductive material is diamond, carbon nanotube or graphene or a combination thereof.

In one embodiment, the diamond is chemically vapor deposited diamond, a nanocrystalline diamond (NCD) coating or sintered diamond powder.

In one embodiment, the carbon nanotube (CNT) is formed with chemical vapor deposition or epitaxial growth.

In one embodiment, the graphene is formed with chemical vapor deposition or epitaxial growth.

In one embodiment, a semiconductor structure is provided having: a crystalline substrate; a single crystalline semiconductor layer grown on the substrate; and a heat generating semiconductor device formed on a portion of the single crystalline layer. The substrate has an aperture entirely through a selected portion thereof disposed under the heat generating semiconductor device, the aperture extending from a bottom portion of the substrate to the single crystalline semiconductor layer. Single crystalline or polycrystalline thermal conductive material is disposed in the aperture, such material filling the aperture and extending from the bottom of the substrate, to and in direct contact with the single crystalline semiconductor layer.

In one embodiment, a semiconductor structure is provided having: a silicon or silicon carbide substrate; a Group III-nitride layer disposed on the substrate; and a field effect transistor having a source region, a drain region and a gate region disposed between the source region and the drain region, the field effect transistor being formed on nitride layer. The substrate has an aperture entirely through the aperture from the substrate to the Group III-nitride layer and under the source region, drain region and gate region. Thermal conductive material such as diamond, carbon nanotube, graphene, or a combination thereof is disposed in the aperture, filling the aperture and extending from the bottom of the substrate to, and in direct contact with, the Group III-nitride layer.

In one embodiment, a semiconductor structure is provided having: a silicon or silicon carbide substrate; a Group III-nitride layer disposed on the substrate; and a heterojunction bipolar transistor having a emitter region, a base region, a collector region, and sub-collector region disposed between the emitter region and the sub-collector region, the heterojunction bipolar transistor being formed on the Group III-nitride layer. The substrate has an aperture entirely through a selected portion thereof disposed under a sub-collector region. Diamond, carbon nanotube, graphene, or a combination thereof filling the aperture and extending from the bottom of the substrate to, and in direct contact with, the Group III-nitride layer.

In one embodiment, a semiconductor structure is provided having: a silicon or silicon carbide substrate; a Group III-nitride compound layer disposed on the substrate; and a p-n junction diode having an anode region and a cathode region disposed between the anode region and the cathode region, the p-n junction diode being formed on the Group III-nitride layer. The substrate has an aperture entirely through a selected portion thereof disposed under a cathode region. Diamond, carbon nanotube, graphene, or a combination of thereof is disposed in the aperture filling the aperture and extending from the bottom of the substrate to, and in direct contact with, the Group III-nitride layer.

In one embodiment a method is provided for forming a semiconductor structure, comprising: growing a Group III-nitride layer on top of a SiC or Si substrate; selectively removing portions of the SiC or Si disposed under selected regions of the Group III-nitride layer, such etching terminating at the Group III-nitride layer; and filling the etched region with diamond, carbon nanotube, graphene, or a combination of thereof extending from the bottom of the substrate to, and in direct contact with, the Group III-nitride layer.

With such an arrangement, diamond, carbon nanotube, graphene, or a combination thereof is disposed underneath the active diode or transistor areas, so called, ‘hot zone’ that generate the most of heat during the operation of heat generating semiconductor devices. For example, the ‘hot zone’ of FETs is between gate and drain, which has the highest electric field during the high voltage and high current operation. For-example, the ‘hot zone’ of HBTs is between base and collector, which has the highest electric field during the high voltage and high current operation. Thus, while common substrates used for Group III-Nitride based Diodes, FETs and HBTs are SiC and Silicon, and AlN or AlN compounds is a common transition buffer layer material to grow Group III-Nitride based active layers on top of SiC or Si substrates, in accordance with the present disclosure high thermally conductive materials such as synthetic diamond (CVD diamond, nanocrystalline diamond (NCD) coating, or sintered diamond powder), carbon nanotube, graphene, or a combination thereof are formed under the hot zones before the growth of active layers for the diodes, FETs, and HBTs so that both the growth of Group III-Nitride active layers and the wafer fabrication of the diodes, FETs, and HBTs are not affected by the process and procedures to fill up these high thermal conductive materials on SiC or silicon substrate with apertures.

Thus, the inventors have recognized that having the synthetic diamond (CVD diamond, nanocrystalline diamond (NCD) coating, or sintered diamond powder), carbon nanotube, graphene, or a combination of these high thermal conductive materials under the heat generating semiconductor device and filling the aperture with the diamond, carbon nanotube, graphene, or a combination of these high thermal conductive materials minimal results in minimal thermal stresses between the substrate and the high thermal conductive materials such as synthetic diamond, carbon nanotube, graphene, or a combination of the high thermal conductive materials.

The details of one or more embodiments of the disclosure are set forth in the accompanying drawings and the description below. Other features, objects, and advantages of the disclosure will be apparent from the description and drawings, and from the claims.

### BRIEF DESCRIPTION OF THE DRAWINGS

FIGS. 1A-1F are diagrammatic, cross sectional views of a Field Effect Transistor (FET) semiconductor structure at various stages in the fabrication thereof according to the disclosure;

FIG. 1C′ is diagrammatic, cross sectional view of a Field Effect Transistor (FET) semiconductor structure at one various stages in the fabrication thereof according to an alternative embodiment of the process in FIG. 1A-1F;

FIG. 2 is a diagrammatic, cross sectional sketch of a diode semiconductor structure according to another embodiment of the disclosure;

FIG. 3 is a diagrammatic, cross sectional sketch of a heterojunction bipolar transistor (HBT) semiconductor structure according to another embodiment of the disclosure the disclosure; and

FIG. 4 is a top view of a Monolithic Microwave Integrated Circuit (MMIC) having a plurality of the FETs according to the disclosure.

Like reference symbols in the various drawings indicate like elements.

### DETAILED DESCRIPTION

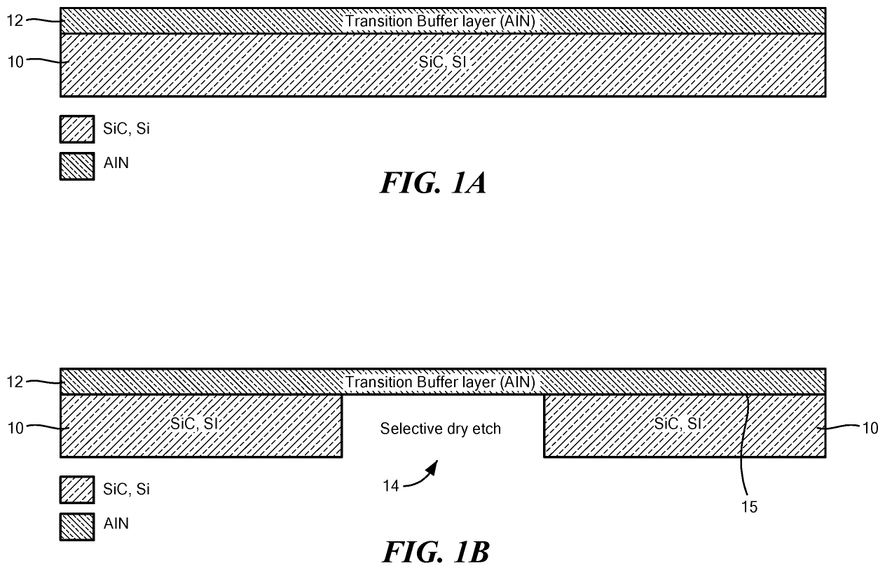

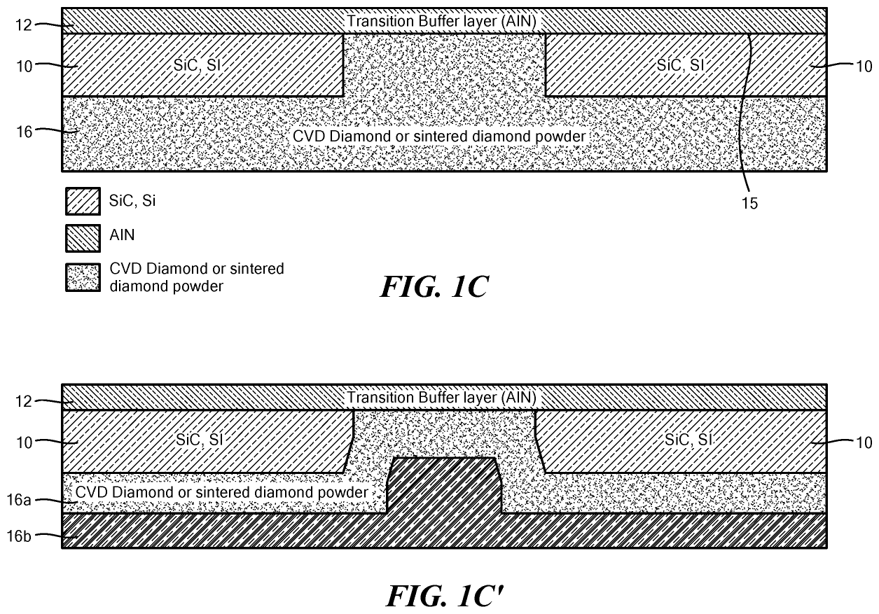

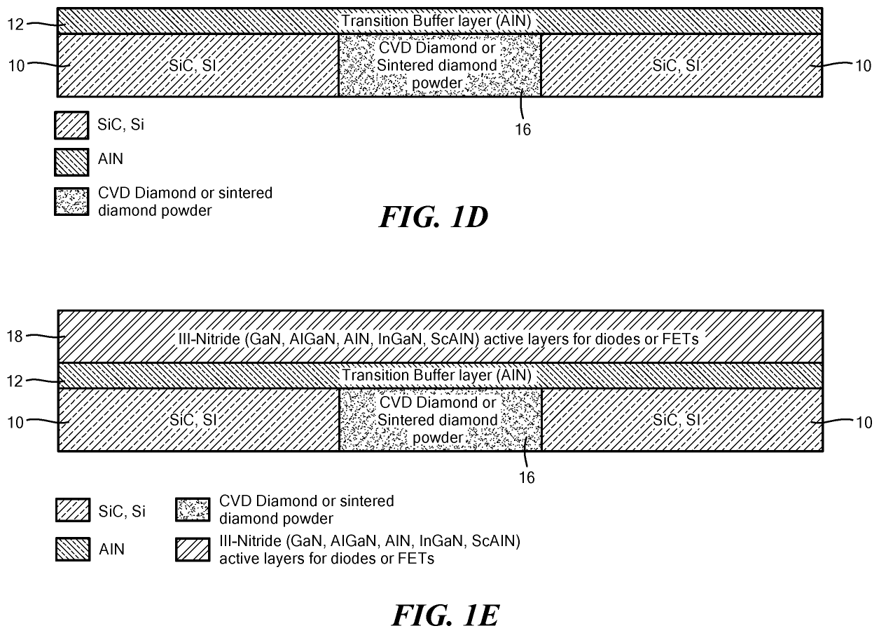

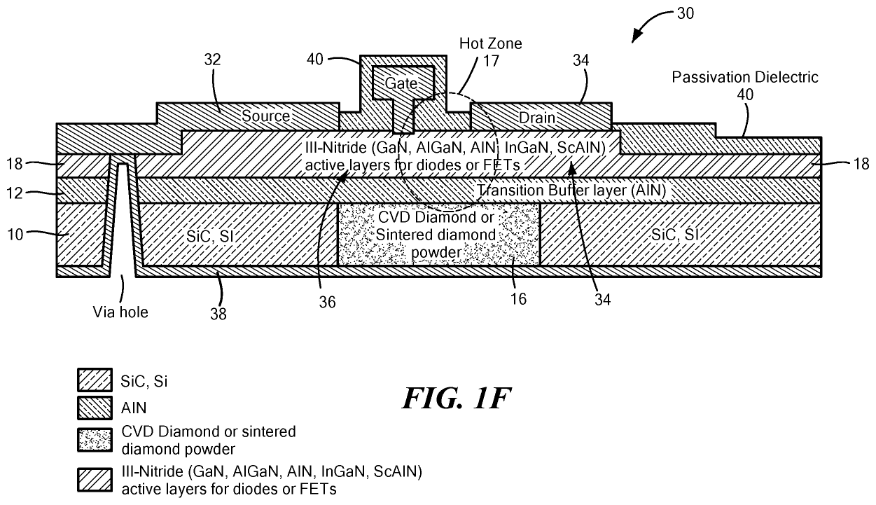

Referring now to FIG. 1A, a crystalline wafer herein referred to as a substrate 10, here for example silicon (Si) or silicon carbide (SiC) is provided. An aluminum nitride (AlN) transition buffer layer 12 is epitaxially grown on the upper surface of the substrate 10, as shown. The transition buffer layer can be any combination and variation of AlN, GaN, and AlGaN materials.

Referring now to FIG. 1B, an aperture 14 is etched entirely through a selected portion of the substrate such aperture extending from the bottom of the substrate 10 vertically through the entire substrate 10 to the bottom of the aluminum nitride (AlN) etch stop, transition buffer layer 12 as shown using semiconductor processes to open the aperture with photolithography, mask, and etching processes. Selective dry etch technology, here for example, sulfur hexafluoride (SF6), etches off the substrate materials, SiC or Si, underneath of the hot zones of heat generating devices, not shown and to be formed, and the etch stops at, and thereby exposes a selected portion 15 of the bottom surface of the AlN etch stop, transition buffer layer 12, as shown.

Referring now to FIG. 1C, a material 16 having a higher thermal conductivity than the substrate 10, here for example a non-electrically conductive, single crystalline or polycrystalline, for example a synthetic diamond, here for example a Chemically Vapor Deposited (CVD) diamond is formed over the back or bottom surface of the substrate 10 and through the aperture 14 filling the aperture 14 and being directly deposited onto the exposed bottom portion 15 of the AlN transition buffer layer 12 and thus fills up the etched aperture 14, as shown It is noted that fast CVD growth has been reported in the literature as 100 um an hour. If CVD growth is slow, the etched apertures 14 can be filled with sintered diamond powder. Nanocrystalline diamond (NCD) film is another option to fill up the etched areas. If NCD growth is slow, the etched areas can be filled with diamond powder and sintered and then Carbon nanotube (CNT) or graphene layer 16b (FIG. 1C′) can be deposited on top of CVD diamond, NCD diamond, or sintered diamond powder layer 16a, as shown in FIG. 1C′ to provide the high thermally conductive layer designated material 16 in FIG. 1C.

Referring now to FIG. 1D, SiC or Si substrate 10 with synthetic diamond, CNT, graphene, or a combination of the synthetic diamond, CNT, graphene, three high thermal conductive materials 16 filling the aperture 14 is polished to remove an extra synthetic diamond, CNT, graphene, or a combination of the three high thermal conductive materials 16 in the aperture 14; under the hot zone 17 between the gate region under gate contact 36 and drain region under drain contact 34, as shown in FIG. 1F.

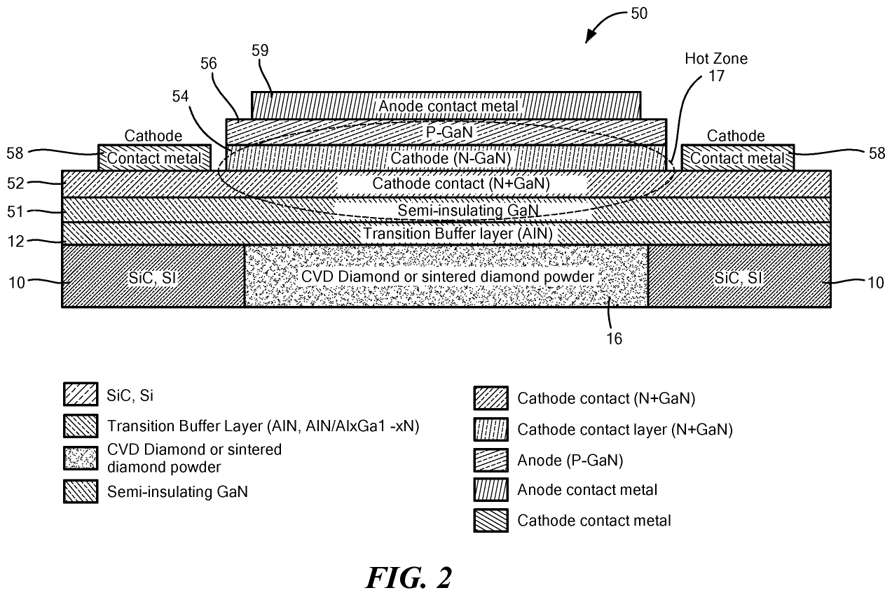

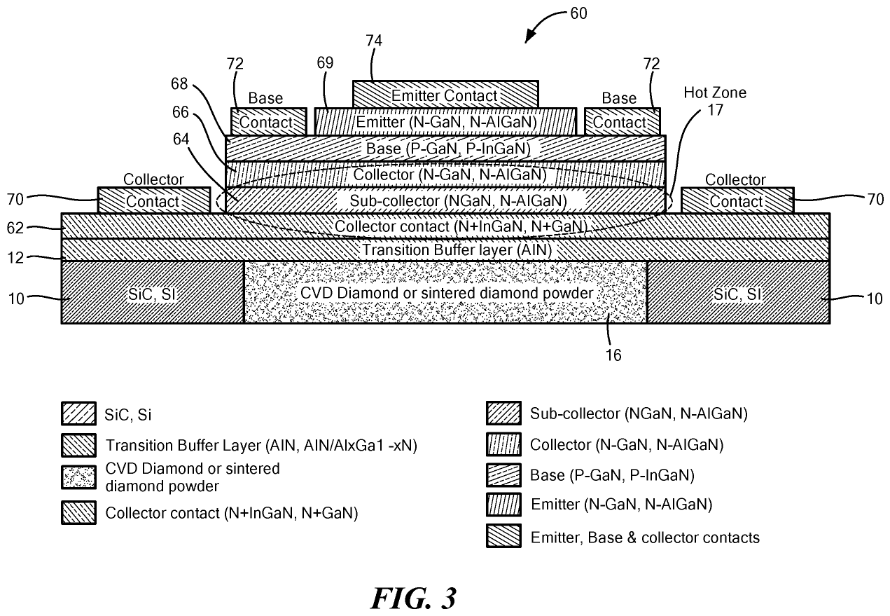

Referring now to FIG. 1E, the thickness of AlN layer transition buffer layer 12 can be adjusted, for example by growth polishing it down, if necessary and any kind of Group III-Nitride based active Diodes, FETs, and HBT semiconductor layer structures (FIGS. 2 and 3, respectively) can be grown on the SiC or Si with synthetic diamond, CNT, graphene, or a combination these three high thermal conductive materials filled up in the aperture below; more particularly in layered structure 18. Group III-Nitride structure (GaN, AlGaN, AlN, InGaN, SLAIN), for example, as shown in FIG. 1E.

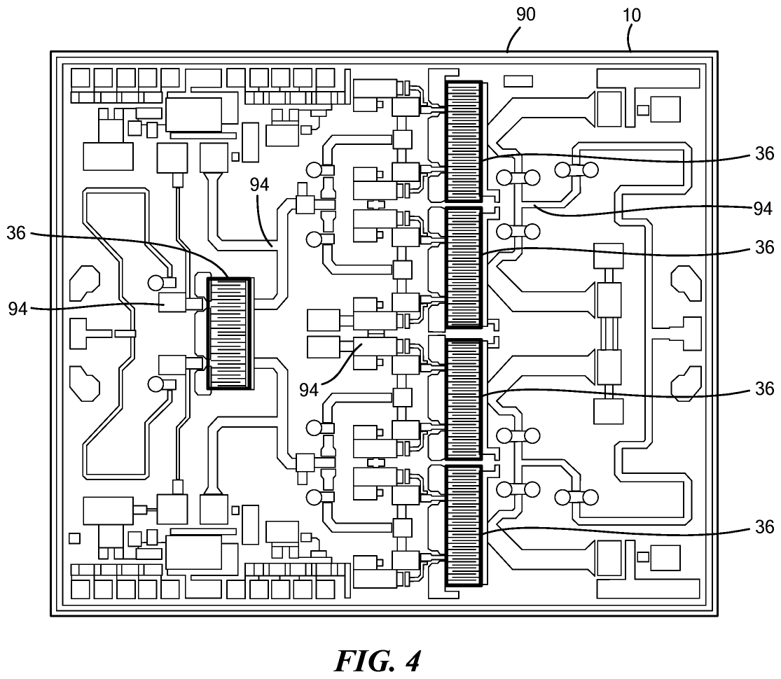

Referring now to FIG. 1F, here the heat generating device is an active device, here a Field Effect Transistor (FET) 30 having a source region under source contact 32, a drain region under drain contact 34 and a gate region under gate contact 36 disposed between the source region and the drain region. Here, the FET 30 will be a grounded source contact 32 in FET 30 so a conductive via/ground plane conductor 38 is formed through the layered structure 18, the AlN transition buffer layer 12, and through the substrate 10 using any conventional photolithographic back-side etching process. It should be understood that while FET 30 is shown for simplicity as having a single gate contact 36, such FET would typically have a plurality of gate contacts interconnected to a common gate electrode, each gate contact being disposed between a source contact and a contact, as shown in FIG. 4.

A conventional passivation layer 40 is provided, as shown. It is noted that the synthetic diamond, CNT, graphene, or a combination of these three materials 16 is disposed under the hot zone of the heat generating semiconductor device FET 30

Referring now to FIG. 2, here the semiconductor structure is another type of heat generating active device, a diode 50. Thus, here again the structure 50 includes a silicon carbide (SiC) or silicon (Si) substrate 10, a transition buffer layer of aluminum nitride (AlN) 12 wherein the substrate 10 has an aperture filled with synthetic diamond, CNT, graphene, or a combination of these three high thermal conductive materials, formed as described above in connection with FIGS. 1A-1F.

The diode 50, here, for example, includes a semi-insulating (SI) gallium nitride layer (GaN) on the transition buffer layer 12, a cathode contact layer 52 of here N+ GaN on the semi-insulating layer 51, a cathode layer 54 of N− GaN on the cathode contact layer 52, a P-layer of GaN 56 on the cathode layer 54. A cathode contact 58 is provide in contact with cathode contact layer 52 and an anode contact 59 is provide in contact with the P—GaN layer 56, all formed with conventional processing. Note that a hot zone 17 is generated across the junctions between layers 51, 52, 54 and 56, as indicated.

Referring now to FIG. 3, here the semiconductor structure is another type of heat generating active device, a heterojunction bipolar transistor (HBT) 60. Thus, here again the structure 60 includes a silicon carbide (SiC) or silicon (Si) substrate 10, a transition buffer layer of aluminum nitride (AlN) 12 wherein the substrate 10 has an aperture filled with the synthetic diamond, CNT, graphene, or a combination of these three high thermal conductive materials, formed as described above in connection with FIGS. 1A-1F.

The HBT 60, here, for example, includes a collector contact layer 62 of N+InGaN or N+GaN on the transition buffer layer 12, a N−GaN or N−AlGaN sub-collector layer 64 on layer 62, a N−GaN or N−AlGaN collector layer 66 on layer 64, a P—GaN or P—InGaN base layer 68 on layer 66, an N−GaN or N−AlGaN emitter layer 69 on layer 68. A collector contact 70 is formed in contact with the collector contact layer 62, a base contact 72 is in contact with layer 68, and an emitter contact 74 is in contact with the emitter layer 69 all formed with conventional processing. Note that a hot zone 17 is generated across the junctions between layers 64 and 62, as indicated.

Referring now to FIG. 4, a MIMIC 90 is shown having substrate 10 on the upper surface thereof heat generating, active devices, here multi-gate configurations FET 36, and passive non-heat generating devices 94, such as power combiners, power splitters, and passive devices such as resistors and capacitors, microwave transmission lines. It is noted that the high thermal conductive materials 16 (synthetic diamond, CNT, graphene, or a combination of these three high thermal conductive materials) is disposed only under the active devices 92 and absent from being under the passive devices 94.

A number of embodiments of the disclosure have been described. Nevertheless, it will be understood that various modifications may be made without departing from the spirit and scope of the disclosure. For example, the transition layer 12 may be AlN/AlₓGa₁₋ₓN, where x ix a number from 0 to 1. The disclosure can be applied to any variation of Group III-nitride compound buffer layer and active layer materials on top of SiC and silicon substrate. Accordingly, other embodiments are within the scope of the following claims.

What is claimed is:

1. A semiconductor structure, comprising:
a crystalline substrate;
a single crystalline semiconductor layer grown on the substrate;
a heat generating semiconductor device formed on a portion of the crystalline layer;
wherein the substrate has an aperture in a selected portion thereof disposed under the heat generating semiconductor device, the aperture extending from a bottom portion of the substrate to the single crystalline semiconductor layer; and
single crystalline or polycrystalline thermally heat conductive material disposed in the aperture, such material filling the aperture and extending from the bottom of the substrate, to and in direct contact with, the semiconductor layer.

2. The structure recited in claim 1 wherein the substrate is silicon or silicon carbide.

3. The structure recited in claim 1 wherein the heat generating device is a transistor or diode.

4. The structure recited in claim 1 wherein the semiconductor layer is a Group III-nitride.

5. The structure recited in claim 1 wherein the single crystalline or polycrystalline is a thermally heat conductive material disposed in the aperture.

6. The structure recited in claim 5 wherein the single crystalline or polycrystalline is chemically vapor deposited diamond, Nanocrystalline diamond (NCD), sintered diamond powder, carbon nanotube, graphene, or a combination thereof.

7. The semiconductor structure recited in claim 1 wherein the single crystalline or polycrystalline thermally heat conductive material is electrically non-conducting.

8. The structure recited in claim 1 wherein the heat generating device is a diode.

9. The structure recited in claim 7 wherein the heat generating device is a transistor.

10. The structure recited in claim 7 wherein the semiconductor layer is a Group III-nitride.

11. The structure recited in claim 7 wherein the heat generating device is a diode.

12. The structure recited in claim 11 wherein the thermally heat conductive material is synthetic diamond, carbon nanotube, graphene, or a combination thereof.

13. A semiconductor structure, comprising:
a silicon or silicon carbide substrate;
a single crystalline layer disposed on the substrate;
a plurality of active devices disposed on the single crystalline layer and passive devices disposed on the substrate;
wherein the substrate has a plurality of apertures in selected portions thereof disposed under the plurality of active devices and absent from a regions under the passive devices; and
single crystalline or polycrystalline material disposed in the apertures, filling the apertures and extending from the bottom of the substrate to, and in direct contact with, the single crystalline layer.

14. The semiconductor structure recited in claim 13 wherein the single crystalline or polycrystalline material is chemically vapor deposited diamond, Nanocrystalline diamond (NCD), sintered diamond powder, carbon nanotube, graphene, or a combination of thereof.

15. A semiconductor structure, comprising:
a crystalline substrate;
a single crystalline semiconductor layer grown on the substrate;
a heat generating semiconductor device formed on a portion of the single crystalline layer;
wherein the substrate has an aperture in a selected portion thereof disposed under a heat generating portion of the heat generating semiconductors device generating the most heat, the aperture extending from a bottom portion of the substrate to the single crystalline semiconductor layer; and
single crystalline or polycrystalline thermally heat conductive material disposed in the aperture, such material filling the aperture and extending from the bottom of the substrate, to and in direct contact with, the semiconductor layer.

16. The structure recited in claim 15 wherein the substrate is silicon or silicon carbide.

17. The structure recited in claim 15 wherein the heat generating device is a transistor or diode.

18. The structure recited in claim 15 wherein the semiconductor layer is a Group III-nitride.

19. The structure recited in claim 15 wherein the single crystalline or polycrystalline material is a thermally heat conductive material disposed in the aperture.

20. The structure recited in claim 19 wherein the thermally heat conductive material is synthetic diamond, graphene, or a combination thereof.

21. A method for forming a semiconductor structure, comprising:
growing a nitride layer on top of a SiC or Si substrate;
selectively removing portions of the SiC or Si disposed under selected regions of the nitride layer, such etching terminating at the nitride layer; and
filling the etched region with synthetic diamond, carbon nanotube, graphene, or a combination of thereof.

22. A semiconductor structure, comprising:
a silicon or silicon carbide substrate;
a Group III-nitride compound layer disposed on the substrate;
a heterojunction bipolar transistor having an emitter region, a base region, a collector region, and sub-collector region disposed between the emitter region and the sub-collector region, the heterojunction bipolar transistor being formed on the Group III-nitride layer;
wherein the substrate has an aperture in a selected portion thereof disposed under a sub-collector region; and
synthetic diamond, carbon nanotube, graphene, or a combination thereof disposed in the aperture, filling the aperture and extending from the bottom of the substrate to, and in direct contact with, the Group III-nitride layer.

23. A semiconductor structure, comprising:
a silicon or silicon carbide substrate;
a Group III-nitride compound layer disposed on the substrate;
a p-n junction diode having an anode region and a cathode region disposed between the anode region and the cathode region, the p-n junction diode being formed on the Group III-nitride layer;
wherein substrate has an aperture in a selected portion thereof disposed under a cathode region; and
synthetic diamond, Nanocrystalline diamond (NCD), sintered diamond powder, carbon nanotube, graphene, or a combination of thereof disposed in the aperture, filling the aperture and extending from the bottom of the substrate to, and in direct contact with, the Group III-nitride layer.
